(19) United States
(12) Patent Application Publication
(10) Pub. No.: US 2011/0017586 A1
(43) Pub. Date: Jan. 27, 2011

(54) Method for forming silicon oxide film, storage medium, and plasma processing apparatus

(75) Inventors: Hideo Nakamura, Amagasaki-City (JP); Yoshiro Kabe, Amagasaki-City (JP); Junichi Kitagawa, Amagasaki-City (JP)

Correspondence Address: SMITH, GAMBRELL & RUSSELL, 1130 CONNECTICUT AVENUE, N.W., SUITE 1130, WASHINGTON, DC, 20036, US

(73) Assignee: TOKYO ELECTRON LIMITED, Tokyo-to (JP)

(21) Appl. No.: 12/805,301

(22) Filed: Jul. 22, 2010

Related U.S. Application Data
(63) Continuation-in-part of application No. PCT/JP2009/051517, filed on Jan. 23, 2009.

(30) Foreign Application Priority Data
Jan. 24, 2008 (JP) 2008-013564

(51) Int. Cl. H01L 21/02; B05C 5/02

(52) U.S. Cl. 204/157.43; 118/665; 977/932

(57) ABSTRACT

In oxidation of a silicon having irregularities, a silicon oxide film having a thickness as small as possible is formed in the side wall as compared with the bottom. A plasma is generated, using a plasma processing apparatus (100) which introduces microwave into a chamber (1) through a plane antenna (31) having plural microwave radiating holes (32), while applying a high-frequency power to a stage (2), under the conditions that the proportion of oxygen in the processing gas is in the range of 0.1 to 50% and the processing pressure is in the range of 1.3 to 667 Pa. By using this plasma, the ratio of the thickness of the silicon oxide film formed on the side wall surfaces of the irregularities to the thickness of the silicon oxide film formed on the bottom wall surfaces of the recessed portions of the irregularities is made not more than 0.6, while the thickness of the silicon oxide films formed on the bottom wall surfaces is not less than 6 nm and not more than 20 nm.

### TECHNICAL FIELD

The present invention relates to a method for forming a silicon oxide film, and more particularly to a method for forming a silicon oxide film, which can be applied e.g. to oxidation of trenches formed in a silicon substrate in a semiconductor device manufacturing process, or to oxidation of a three-dimensional line and space pattern after the formation of a gate electrode of a transistor by etching.

### BACKGROUND ART

Shallow trench isolation (STI) is known as a technique for electrically isolating a device formed on a silicon substrate. STI involves etching silicon e.g. with a silicon nitride film as a mask to form trenches, filling an insulating film of e.g. SiO₂ into the trenches, and then flattening the surface by chemical mechanical polishing (CMP) using the mask (silicon nitride film) as a stopper. After the formation of trenches by etching, it is common practice in STI to carry out oxidation of the interior surfaces of the trenches to form a silicon oxide film. The oxidation process is to make the trenches obtuse angled by forming the silicon oxide film, thereby preventing leakage current, etc.

On the other hand, after a gate electrode of a transistor is formed by etching, a similar oxidation process is generally carried out on a three-dimensional line and space pattern in order to repair etching damage.

Methods for forming a silicon oxide film on a silicon surface having irregularities, such as trenches or line and space patterns, can be classified broadly into thermal oxidation using an oxidation furnace or an RTP (rapid thermal process) apparatus, and plasma oxidation using a plasma processing apparatus.

For example, in wet oxidation, one of thermal oxidation methods and which employs an oxidation furnace, a silicon substrate is heated to a temperature exceeding 800° C. and, using a WVG (water vapor generator), the heated silicon substrate is exposed to an oxidizing atmosphere, thereby oxidizing the silicon surface and forming a silicon oxide film.

Thermal oxidation is considered a method capable of forming a good-quality silicon oxide film. Because of the necessity of processing at a high temperature exceeding 800° C., however, thermal oxidation entails the problems of increased thermal budget, distortion of a silicon substrate due to thermal stress, etc.

On the other hand, as a plasma processing method, a method has been proposed which involves forming a microwave-excited plasma at a pressure of 133.3 Pa in a chamber using a processing gas containing argon gas and oxygen gas at an oxygen flow rate ratio of about 1%, and allowing the plasma to act on a silicon surface to oxidize the surface (see e.g. WO2004/008519). The plasma oxidation processing is carried out at a relatively low processing temperature of around 400° C. The method of patent document 1 can therefore avoid the problems of increased thermal budget, distortion of a substrate, etc. Further, this method, by carrying out plasma oxidation under the conditions of a processing pressure on the order of 133.3 Pa and an O₂ flow rate ratio of about 1% in the processing gas (herein referred to as “low-pressure, low-oxygen concentration conditions” for the sake of simplicity), can achieve high oxidation rate and, in addition, has the advantages that when oxidizing a silicon surface having irregularities, a silicon oxide film can be formed with a uniform thickness over the entire surface of the irregularities, and a round shape can be introduced into the top corners of the raised portions of the silicon surface, whereby leakage current from the corner portions due to electric field concentration can be suppressed.

Semiconductor devices are becoming increasingly finer these days, and efforts are being made to enhance the accuracy of pattern dimensions as much as possible. In oxidation processing of a silicon surface having irregularities, such as oxidation of the interior surfaces of trenches in STI or oxidation to repair damage after gate etching, the formation of an oxide film desirably does not much progress laterally on the side wall portions of the irregularities. This is because the progress of lateral formation of an oxide film narrows regions for the production of devices (gate electrodes of transistors, device formation regions in STI, etc.), making the design of fine devices difficult. There is, therefore, a demand for enhancement of the selectivity of oxidation to the bottoms of the irregularities so as to form a thinner oxide film on the side walls of the irregularities, thereby ensuring dimensional accuracy for device regions.

### SUMMARY OF THE INVENTION

The present invention has been made in view of the above situation. It is therefore an object of the present invention to provide a method for forming a silicon oxide film which, in oxidation of a silicon surface having irregularities, can form a silicon oxide film which is thinner in the side walls of the irregularities than in the bottoms.

The present invention provides a method for forming a silicon oxide film by allowing a plasma of a processing gas to act on a silicon portion, exposed on a surface of a processing object having irregularities in the surface, to oxidize the silicon portion in a processing chamber of a plasma processing apparatus, said method comprising generating the plasma under the following conditions: the proportion of oxygen in the processing gas is in the range of 0.1 to 50% by volume; and the processing pressure is in the range of 1.3 to 667 Pa, while applying a high-frequency power to a stage, disposed in the processing chamber and on which the processing object is placed, at a power output in the range of 0.2 to 2.3 W/cm² per unit area of the processing object, whereby the ratio of the thickness of the silicon oxide film formed on the side wall surfaces of the irregularities to the thickness of the silicon oxide film formed on the bottom wall surfaces of the recessed portions of the irregularities [the film thickness in the side wall surfaces/the film thickness in the bottom wall surfaces] is made not more than 0.6.

In the silicon oxide film-forming method of the present invention, the ratio of the thickness of the silicon oxide film formed on the side wall surfaces of the irregularities to the thickness of the silicon oxide film formed on the bottom wall surfaces of the recessed portions of the irregularities [the film thickness in the side wall surfaces/the film thickness in the bottom wall surfaces] may be not less than 0.01 and not more than 0.6, the proportion of oxygen in the processing gas may be in the range of 0.5 to 50% by volume, and the processing pressure may be in the range of 6.7 to 133 Pa.

In the silicon oxide film-forming method of the present invention, it is preferred that the ratio of the thickness of the silicon oxide film formed on the side wall surfaces of the irregularities to the thickness of the silicon oxide film formed on the bottom wall surfaces of the recessed portions of the irregularities [the film thickness in the side wall surfaces/the film thickness in the bottom wall surfaces] be not less than 0.01 and not more than 0.4, the proportion of oxygen in the processing gas be in the range of 0.5 to 25% by volume, and the processing pressure be in the range of 20 to 60 Pa.

In the silicon oxide film-forming method of the present invention, the processing gas may contain hydrogen. In this case, the ratio of the flow rate of hydrogen to the total flow rate of hydrogen and oxygen in the processing gas is preferably in the range of 1% to 90%.

In the silicon oxide film-forming method of the present invention, the frequency of the high-frequency power is preferably in the range of 100 kHz to 60 MHz.

In the silicon oxide film-forming method of the present invention, the processing temperature is preferably in the range of room temperature to 600° C.

In the silicon oxide film-forming method of the present invention, the plasma may be a microwave-excited plasma formed by the processing gas and microwaves introduced into the processing chamber by means of a plane antenna having a plurality of slots. In this case, the power density of the microwaves per unit area of the processing object is preferably in the range of 0.255 to 2.55 W/cm².

In a second aspect, the present invention provides a computer-readable storage medium in which is stored a control program which operates on a computer, said control program, upon its execution, causing the computer to control a plasma processing apparatus such that it carries out a method for forming a silicon oxide film by allowing a plasma of a processing gas to act on a silicon portion, exposed on a surface of a processing object having irregularities in the surface, to oxidize the silicon portion in a processing chamber of the plasma processing apparatus, wherein said plasma is generated under the following conditions: the proportion of oxygen in the processing gas is in the range of 0.1 to 50% by volume; and the processing pressure is in the range of 1.3 to 667 Pa, while applying a high-frequency power to a stage, disposed in the processing chamber and on which the processing object is placed, at a power output in the range of 0.2 to 2.3 W/cm² per unit area of the processing object, whereby the ratio of the thickness of the silicon oxide film formed on the side wall surfaces of the irregularities to the thickness of the silicon oxide film formed on the bottom wall surfaces of the recessed portions of the irregularities [the film thickness in the side wall surfaces/the film thickness in the bottom wall surfaces] is made not more than 0.6.

In a third aspect, the present invention provides a plasma processing apparatus comprising: an open-topped processing chamber for processing a processing object by using a plasma; a dielectric member which closes the opening of the processing chamber; an antenna, provided outside the dielectric member, for introducing electromagnetic waves into the processing chamber; a gas supply mechanism for supplying a raw material gas into the processing chamber; an exhaust mechanism for depressurizing and evacuating the processing chamber; a stage, disposed in the processing chamber, for placing the processing object thereon; a high-frequency power source connected to the stage; and a control section which, when forming a silicon oxide film by oxidizing a silicon portion, exposed on a surface of the processing object having irregularities in the surface, with a plasma of a processing gas in the processing chamber, controls the apparatus such that it generates the plasma by introducing electromagnetic waves into the processing chamber by means of the antenna while applying a high-frequency power to the stage at a power output in the range of 0.2 to 2.3 W/cm² per unit area of the processing object, keeping the proportion of oxygen in the processing gas, supplied by the gas supply mechanism, in the range of 0.1 to 50% by volume, and keeping the processing pressure in the range of 1.3 to 667 Pa by means of the exhaust mechanism, so that the ratio of the thickness of the silicon oxide film formed on the side wall surfaces of the irregularities to the thickness of the silicon oxide film formed on the bottom wall surfaces of the recessed portions of the irregularities [the film thickness in the side wall surfaces/the film thickness in the bottom wall surfaces] is made not more than 0.6.

### BRIEF DESCRIPTION OF THE DRAWINGS

FIG. 1 is a schematic cross-sectional view showing an exemplary plasma processing apparatus suited for carrying out a method for forming a silicon oxide film according to the present invention;

FIG. 2 is a diagram showing the structure of a plane antenna;

FIG. 3 is a diagram illustrating the construction of a control section;

FIGS. 4A through 4I are diagrams illustrating application of the present invention to the formation of a silicon oxide film in trenches in STI;

FIGS. 5A and 5B are diagrams illustrating application of the present invention to the formation of a silicon oxide film to repair damage after etching for the formation of a gate electrode of a transistor;

FIGS. 6A through 6C are diagrams illustrating the relationships between plasma processing conditions and isotropy or anisotropy in oxidation;

FIG. 7 is a diagram illustrating the cross-sectional structure of the surface of a wafer having a three-dimensional pattern;

FIG. 8 is a graph showing the relationship between the proportion of oxygen in a processing gas and the side wall/bottom film thickness ratio in Examples 1 to 3;

FIG. 9 is a graph showing the relationship between the processing pressure and the side wall/bottom film thickness ratio in Examples 2 to 4;

FIG. 10 is a graph showing the relationship between the partial pressure of oxygen in a processing gas and the side wall/bottom film thickness ratio in Examples 1 to 4 and Comp. Example 1;

FIG. 11 is a graph showing the relationship between the plasma oxidation processing time and the average film thickness and the relationship between the plasma oxidation processing time and the in-plane uniformity of the film thickness in wafer surface in Example 1;

FIG. 12 is a graph showing the relationship between the plasma oxidation processing time and the average film thickness and the relationship between the plasma oxidation processing time and the in-plane uniformity of the film thickness in wafer surface in Example 2;

FIG. 13 is a graph showing the relationship between the current density of a high-frequency bias current and the side wall/bottom film thickness ratio in Examples 5 to 8 and Comp. Examples 2 and 3;

FIG. 14 is a graph showing the relationship between the plasma oxidation processing time and the average film thickness and the relationship between the plasma oxidation processing time and the in-plane uniformity of the film thickness in wafer surface in Example 8; and

FIGS. 15A through 15D are diagrams illustrating application of the present invention to the formation of a silicon oxide film in trenches in a flash memory.

### EMBODIMENTS FOR CARRYING OUT THE INVENTION

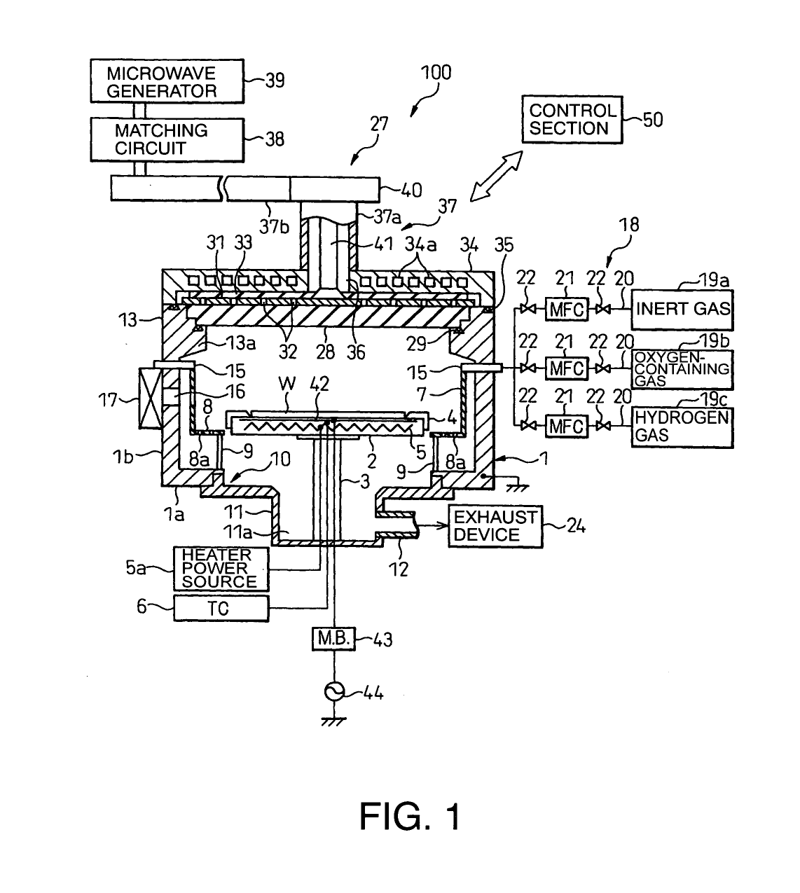

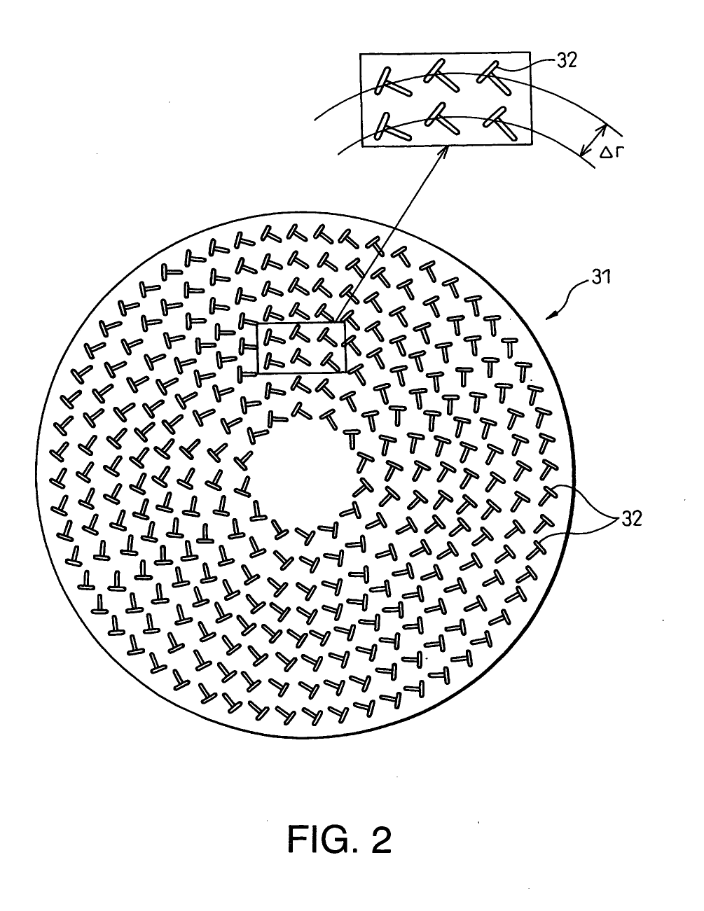

Preferred embodiments of the present invention will now be described in detail with reference to the drawings. FIG. 1 is a cross-sectional view schematically showing the construction of a plasma processing apparatus 100 useful for carrying out a silicon oxide film-forming method according to the present invention. FIG. 2 is a plan view showing the plane antenna of the plasma processing apparatus 100 of FIG. 1.

The plasma processing apparatus 100 is constructed as an RASA microwave plasma processing apparatus capable of generating a high-density, low-electron temperature, microwave-excited plasma by introducing microwaves directly into a processing chamber by means of a plane antenna having a plurality of slot-like holes, in particular an RLSA (radial line slot antenna). The plasma processing apparatus 100 can perform processing with a plasma having a plasma density of 1×10¹⁰ to 5×10¹²/cm³ and a low electron temperature of 0.7 to 2 eV. Other types of plasmas, such as ICP (inductively-coupled plasma), magnetron plasma, ECR (electron cyclotron resonance) plasma and surface wave plasma, can also be used in the present invention. The plasma processing apparatus 100 can therefore be advantageously used to form a silicon oxide film (e.g. SiO₂ film) in the manufacturing of a variety of semiconductor devices.

The plasma processing apparatus 100 comprises the following main components: an airtight chamber (processing chamber) 1; a gas supply mechanism 18 as a gas supply section for supplying a gas into the chamber 1; an exhaust device 24 as an exhaust mechanism for depressurizing and evacuating the chamber 1; a microwave introduction mechanism 27, provided above the chamber 1, for introducing microwaves into the chamber 1; and a control section 50 for controlling these components of the plasma processing apparatus 100.

The chamber 1 is formed by a grounded, generally-cylindrical container. The chamber 1 may be formed by a container of a rectangular cylinder shape. The chamber 1 has a bottom wall 1a and a side wall 1b, e.g. made of aluminum.

In the chamber 1 is provided a stage 2 for horizontally supporting a silicon wafer (wafer W) as a processing object. The stage 2 is made of a material having high thermal conductivity, for example, a ceramic material such as AlN. The stage 2 is supported by a cylindrical support member 3 extending upwardly from the center of the bottom of an exhaust chamber 11. The support member 3 is, for example, made of a ceramic material such as AlN.

The stage 2 is provided with a cover ring 4 for covering a peripheral portion of the stage 2 and guiding the wafer W. The cover ring 4, which may have an annular shape, preferably entirely covers the stage 2. The cover ring 4 can prevent contamination of the wafer W with impurities. The cover ring 4 is, for example, made of quartz, monocrystalline silicon, polysilicon, amorphous silicon or SiN. Of these, quartz is most preferred. Further, such materials for the cover ring 4 preferably are of a high purity, containing little impurities such as an alkali metal, a metal, etc.

A resistance heating-type heater 5 as a temperature adjustment mechanism is embedded in the stage 2. The heater 5, when powered from a heater power source 5a, heats the stage 2 and, by the heat, uniformly heats the wafer W as a processing object.

The stage 2 is provided with a thermocouple (TC) 6. The heating temperature of the wafer W can be controlled e.g. in the range of room temperature to 900° C. by measuring the temperature with the thermocouple 6.

The stage 2 has wafer support pins (not shown) for raising and lowering the wafer W while supporting it. The wafer support pins are each projectable and retractable with respect to the surface of the stage 2.

A cylindrical quarts liner 7 is provided on the inner periphery of the chamber 1. Further, an annular quartz baffle plate 8, having a large number of exhaust holes 8a for uniformly evacuating the chamber 1, is provided around the periphery of the stage 2. The baffle plate 8 is supported on support posts 9.

A circular opening 10 is formed generally centrally in the bottom wall 1a of the chamber 1. The bottom wall 1a is provided with a downwardly-projecting exhaust chamber 11 which communicates with the opening 10. An exhaust pipe 12 is connected to the exhaust chamber 11, and the exhaust chamber 11 is connected via the exhaust pipe 12 to the exhaust device 24.

An annular upper plate 13 is joined to the upper end of the chamber 1. The inner circumference of the plate 13 projects inwardly (toward the inner space of the chamber) and forms an annular support portion 13a.

The side wall 1b of the chamber 1 is provided with an annular gas introduction section 15. The gas introduction section 15 is connected to a gas supply mechanism 18 for supplying an oxygen-containing gas and a plasma excitation gas. It is also possible to construct the gas introduction section 15 in the shape of a nozzle or a shower head.

The side wall 1b of the chamber 1 is also provided with a transfer port 16 for transferring the wafer W between the plasma processing apparatus 100 and an adjacent transfer chamber (not shown), and a gate valve 17 for opening and closing the transfer port 16.

The gas supply mechanism 18 has, for example, an inert gas supply source 19a, an oxygen-containing gas supply source 19b and a hydrogen gas supply source 19c. The gas supply mechanism 18 may also have a not-shown gas supply source(s) other than the above sources, for example, a supply source for a purge gas to be used for replacement of the atmosphere in the chamber 1, or a supply source for a cleaning gas to be used for cleaning of the interior of the chamber 1.

An inert gas is used as a plasma excitation gas and can generate a stable plasma. A rare gas, for example, can be used as an inert gas. Examples of usable rare gases include Ar gas, Kr gas, Xe gas and He gas. Of these, the use of Ar gas is especially preferred from an economical viewpoint. Examples of usable oxygen-containing gases include oxygen (O₂) gas, water vapor (H₂O), nitrogen monoxide (NO) and dinitrogen monoxide (N₂O).

An inert gas, an oxygen-containing gas and hydrogen gas, respectively from the inert gas supply source 19a, the oxygen-containing gas supply source 19b and the hydrogen gas supply source 19c of the gas supply mechanism 18, each pass through a respective gas line 20 and reach the gas introduction section 15, and is introduced from the gas introduction section 15 into the chamber 1. The respective gas line 20 connected to each gas supply source is provided with a mass flow controller 21 and on-off valves 22 located upstream and downstream of the controller 21. Such construction of the gas supply mechanism 18 enables switching of the gases supplied and control of the flow rate of each gas, etc.

The exhaust device 24 as an exhaust mechanism includes a vacuum pump, e.g. a high-speed vacuum pump such as a turbo-molecular pump. As described above, the exhaust device 24 is connected via the exhaust pipe 12 to the exhaust chamber 11 of the chamber 1. By the actuation of the exhaust device 24, the gas in the chamber 1 uniformly flows into the space 11a of the exhaust chamber 11, and is discharged from the space 11a through the exhaust pipe 12 to the outside. The chamber can thus be quickly depressurized into a predetermined vacuum, e.g. 0.133 Pa.

The construction of the microwave introduction mechanism 27 will now be described. The microwave introduction mechanism 27 mainly comprises a transmissive plate 28, a plane antenna 31 as an antenna, a retardation member 33, a metal cover 34, a waveguide 37, a matching circuit 38 and a microwave generator 39.

The transmissive plate 28, which is permeable to microwaves, is supported on the inwardly-projecting support portion 13a of the upper plate 13. The transmissive plate 28 is composed of a dielectric material, for example, quartz or a ceramic material such as Al₂O₃, AlN, etc. The transmissive plate 28 and the support portion 13a are hermetically sealed with a seal member 29, so that the chamber 1 is kept hermetic.

The plane antenna 31 as an antenna is provided over the transmissive plate 28 (outside the chamber 1) such that it faces the stage 2. The plane antenna 31 has a disk-like shape. The shape of the plane antenna 31 is not limited to a disk-like shape: For example, the antenna may be of a square plate-like shape. The plane antenna 13 is locked into the upper end of the upper plate 13.

The plane antenna 31 is comprised of a conductive member, for example, a copper plate, an aluminum plate, a nickel plate or a plate of an alloy thereof, whose surface is plated with gold or silver. The plane antenna 31 has a large number of slot-like microwave radiating holes 32 that radiate microwaves. The microwave radiating holes 32, which penetrate through the plane antenna 31, are formed in a predetermined pattern.

Each microwave radiating hole 32 is a (slot-shaped) narrow opening as shown in FIG. 2. Adjacent two microwave radiating holes 32 are paired typically in a letter “T” arrangement. The microwave radiating holes 32, comprised of such pairs in a predetermined arrangement (e.g. letter “T” arrangement), are arranged in concentric circles as a whole.

The length of the microwave radiating holes 32 and the spacing in their arrangement are determined depending on the wavelength (λg) of microwaves. For example, the microwave radiating holes 32 are arranged with a spacing of λg/4, λg/2 or λg. In FIG. 2, the spacing between adjacent concentric lines of microwave radiating holes 32 is denoted by Δr. The microwave radiating holes 32 may have other shapes, such as a circular shape and an arch shape. The arrangement of the microwave radiating holes 32 is not limited to concentric circles: For example, the microwave radiating holes 32 may be arranged in a spiral or radial arrangement.

The retardation member 33, having a higher dielectric constant than vacuum, is provided on the upper surface of the plane antenna 31. The retardation member 33 is employed in consideration of the fact that the wavelength of microwaves becomes longer in vacuum. The retardation member 33 functions to shorten the wavelength of microwaves, thereby adjusting a plasma. Quartz, a polytetrafluoroethylene resin or a polyimide resin, for example, may be used as a material for the retardation member 33.

The plane antenna 31 and the transmissive plate 28, and the retardation member 33 and the plane antenna 31 may be in contact with or spaced apart from each other, though preferably be in contact with each other.

The metal cover 34 is provided over the chamber 1 such that it covers the plane antenna 31 and the retardation member 33. The metal cover 34 is formed of a metal material such as aluminum or stainless steel. A flat waveguide is formed by the metal cover 34 and the plane antenna 31, so that microwaves can be supplied uniformly into the chamber 1. The upper end of the upper plate 13 and the metal cover 34 are sealed with a seal member 35. A cooling water flow passage 34a is formed in the interior of the metal cover 34. The metal cover 34, the retardation member 33, the plane antenna 31 and the transmissive plate 28 can be cooled by passing cooling water through the cooling water flow passage 34a. The metal cover 34 is grounded.

An opening 36 is formed in the center of the upper wall (ceiling) of the metal cover 34, and the waveguide 37 is connected to the opening 36. The other end of the waveguide 37 is connected via the matching circuit 38 to the microwave generator 39 that generates microwaves.

The waveguide 37 is comprised of a coaxial waveguide 37a having a circular cross-section and extending upward from the opening 36 of the metal cover 34, and a horizontally-extending rectangular waveguide 37b connected via a mode converter 40 to the upper end of the coaxial waveguide 37a. The mode converter 40 functions to convert microwaves, propagating in TE mode through the rectangular waveguide 37b, into TEM mode microwaves.

An inner conductor 41 extends centrally in the coaxial waveguide 37a. The inner conductor 41, at its lower end, is connected and secured to the center of the plane antenna 31. With such construction, microwaves are propagated through the inner conductor 41 of the coaxial waveguide 37a to the flat waveguide, formed by the plane antenna 31, radially, efficiently and uniformly.

An electrode 42 is embedded in the front surface of the stage 2. A high-frequency power source 44 for bias application is connected via a matching box (M.B.) 43 to the electrode 42, so that a bias can be applied to the wafer W (processing object) by supplying a high-frequency bias power to the electrode 42. A conductive material, such as molybdenum or tungsten, can be used as a material for the electrode 42. The electrode 42 may be formed e.g. in a net-like shape, a grid-like shape or a spiral shape.

With the microwave introduction mechanism 27 thus constructed, microwaves generated in the microwave generator 39 are propagated through the waveguide 37 to the plane antenna 31 and introduced, via the microwave radiating holes (slots) 32 and the transmissive plate 28, into the chamber 1. An exemplary microwave frequency which is preferably used is 2.45 GHz. Other frequencies such as 8.35 GHz and 1.98 GHz can also be used.

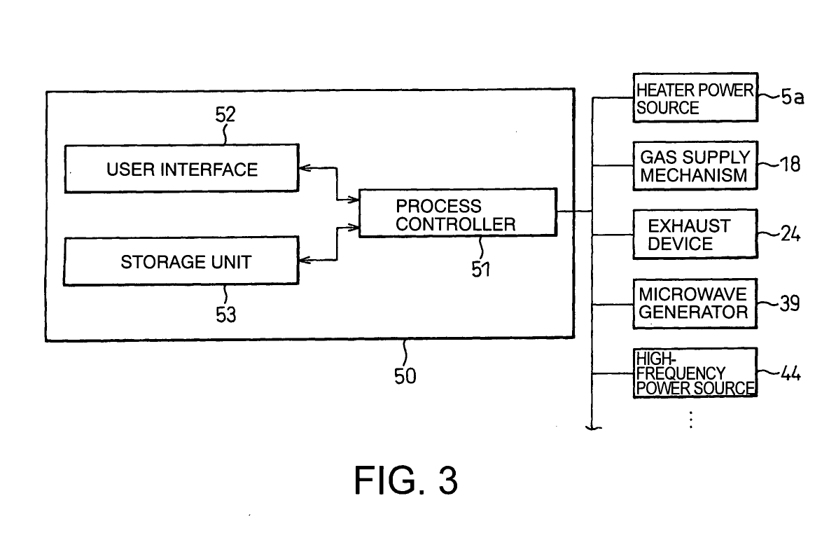

The components of the plasma processing apparatus 100 are each connected to and controlled by the control section 50. The control section 50 typically is a computer and, as shown in FIG. 3, includes a process controller 51 provided with a CPU, and a user interface 52 and a storage unit 53, both connected to the process controller 51. The process controller 51 is a control means which comprehensively controls those components of the plasma processing apparatus 100 which are related to process conditions, such as temperature, pressure, gas flow rate, microwave power, high-frequency power for bias application, etc. (heater power source 5a, gas supply mechanism 18, exhaust device 24, microwave generator 39, high-frequency power source 44, etc.).

The user interface 52 includes a keyboard for a process manager to perform a command input operation, etc. in order to manage the plasma processing apparatus 100, a display which visualizes and displays the operating situation of the plasma processing apparatus 100, etc. In the storage unit 53 are stored a control program (software) for executing, under control of the process controller 51, various processings to be carried out in the plasma processing apparatus 100, and a recipe in which data on processing conditions, etc. is recorded.

A desired processing is carried out in the chamber 1 of the plasma processing apparatus 100 under the control of the process controller 51 by calling up an arbitrary recipe from the storage unit 53 and causing the process controller 51 to execute the recipe, e.g. through the operation of the user interface 52 performed as necessary. With reference to the process control program and the recipe of processing condition data, etc., it is possible to use those stored in a computer-readable storage medium, such as CD-ROM, hard disk, flexible disk, flash memory, DVD, blu-ray disc, etc. or to transmit them from another device e.g. via a dedicated line.

The plasma processing apparatus 100 thus constructed enables plasma processing to be carried out at a low temperature of not more than 600° C., e.g. from room temperature (about 25° C.) to 600° C., without damage e.g. to a base film formed on a processing object or to a substrate (wafer W). Further, the plasma processing apparatus 100 is excellent in the uniformity of plasma, and can therefore achieve uniform processing even for a large diameter wafer W (processing object).

A description will now be given of plasma oxidation processing carried out by using the RLSA-type plasma processing apparatus 100. First, the gate valve 17 is opened, and a wafer W is carried from the transfer port 16 into the chamber 1 and placed on the stage 2.

Next, while depressurizing and evacuating the chamber 1 by means of the vacuum pump, an inert gas and an oxygen-containing gas, and optionally hydrogen gas, are supplied from the inert gas supply source 19a, the oxygen-containing gas supply source 19b and the hydrogen gas supply source 19c of the gas supply mechanism 18 and introduced through the gas introduction section 15 into the chamber 1 respectively at a predetermined flow rate. The pressure in the chamber 1 is thus adjusted to a predetermined pressure.

Next, microwaves having a predetermined frequency, for example 2.45 GHz, generated by the microwave generator 39, are introduced via the matching circuit 38 into the waveguide 37. The microwaves introduced into the waveguide 37 pass through the rectangular waveguide 37b, the coaxial waveguide 37a and the inner conductor 41, and are supplied to the plane antenna 31. The microwaves propagate in TE mode in the rectangular waveguide 37b. The TE mode microwaves are converted into TEM mode microwaves by the mode converter 40, and the TEM mode microwaves are propagated in the coaxial waveguide 37a toward the plane antenna 31. The microwaves are then radiated from the slot-like microwave radiating holes which penetrate through the plane antenna 31, and introduced through the transmissive plate 28 as a dielectric body into the space over the wafer W in the chamber 1. The microwave power output, in terms of the power density, can be selected e.g. from the range of 0.255 to 2.55 W/cm² when the wafer W has a diameter of not less than 200 mm.

By the microwaves radiated from the plane antenna 31 into the chamber 1 via the transmissive plate 28, an electromagnetic field is formed in the chamber 1, and the inert gas and the oxygen-containing gas turn into a plasma. Because the microwaves are radiated from the large number of microwave radiating holes 32 of the plane antenna 31, the microwave-excited plasma has a high density of about 1×10¹⁰ to 5×10¹²/cm³ and, in the vicinity of the wafer W, has a low electron temperature of not more than about 1.2 eV. The plasma thus formed causes little damage, e.g. by ions, to the substrate (wafer W). By the action of active species, such as radicals and ions, in the plasma, the surface silicon (monocrystalline silicon, polycrystalline silicon or amorphous silicon) of the wafer W is oxidized and a damage-free silicon oxide film is formed.

During the plasma oxidation processing, a high-frequency power, having a predetermined frequency and a predetermined power, is supplied from the high-frequency power source 44 to the stage 2. A high-frequency bias voltage (high-frequency bias) is applied to the substrate by the high-frequency power supplied from the high-frequency power source 44. This promotes anisotropic plasma oxidation while maintaining the low electron temperature of the plasma. In particular, the application of the high-frequency bias to the substrate generates an electromagnetic field in the vicinity of the substrate. The electromagnetic field acts to draw ions in the plasma to the substrate (wafer W), which weakens the oxidizing action of ions on the side walls of irregularities of the silicon surface and therefore lowers the oxidation rate for those portions. The electromagnetic field, on the other hand, acts to increase the oxidation rate for the bottom walls of the recessed portions of the surface irregularities. Thus, isotropic oxidation is suppressed and the formation of an oxide film less progresses laterally on the side walls of the irregularities of the silicon surface. The dimensional accuracy of the three-dimensional pattern of the wafer can therefore be maintained. On the other hand, because ions are drawn to the bottoms of the recessed portions by the high-frequency bias, a silicon oxide film having a sufficient thickness can be formed on the bottoms.

### <Plasma Oxidation Conditions>

Preferred conditions for plasma oxidation processing carried out in the plasma processing apparatus 100 will now be described. With reference to a processing gas, it is preferred to use Ar gas as a rare gas and O₂ gas as an oxygen-containing gas. From the viewpoint of enhancing anisotropy in plasma processing so as to promote oxidation of the bottoms of recessed portions of surface irregularities while suppressing oxidation of the side walls of the surface irregularities, the flow rate ratio (volume ratio) of O₂ gas in the processing gas is preferably in the range of 0.1% to 50%, more preferably in the range of 0.5% to 25%, further more preferably in the range of 0.5% to 10%, and desirably in the range of 0.1% to 1%. This is because when a plasma is formed at a low oxygen partial pressure in the chamber, the partial pressure of oxygen (ions) in the recessed portions is further low. Therefore, oxygen ions are drawn to the bottoms of the recessed portions, whereby the action of oxygen ions on the side walls weakens.

In this embodiment the processing gas may contain hydrogen. When the processing gas contains hydrogen, OH radicals are generated in the plasma, which can increase the oxidation rate. When hydrogen is used, in order to obtain a high oxidation rate, the flow rate ratio (volume ratio) of the sum of hydrogen and oxygen to the entire processing gas is preferably in the range of 0.1% to 50%, more preferably in the range of 0.5% to 25%, further more preferably in the range of 0.5% to 10%, and desirably in the range of 0.1% to 1%. Further, the ratio of the flow rate of hydrogen to the total flow rate of hydrogen and oxygen ([H₂ flow rate/(total flow rate of H₂+O₂)]×100) is preferably set in the range of 1% to 90%, more preferably in the range of 10% to 60% from the viewpoint of increasing the oxidation rate for the bottoms of recessed portions, and desirably in the range of 1% to 50% from the viewpoint of forming a silicon oxide film which is selectively thinner in the side walls of surface irregularities than in the bottoms of the recessed portions of the irregularities.

From the viewpoint of enhancing anisotropy in plasma processing so as to promote oxidation of the bottoms of recessed portions of surface irregularities while suppressing oxidation of the side walls of the surface irregularities, the processing pressure is preferably set in the range of 1.3 to 667 Pa, more preferably in the range of 6.7 to 133 Pa, and desirably in the range of 20 to 60 Pa.

A preferred combination of the oxygen flow rate ratio in the processing gas and the processing pressure is as follows: When it is intended to make the ratio of the thickness of a silicon oxide film in the side wall surfaces of surface irregularities to the thickness of a silicon oxide film in the bottom wall surfaces of the recessed portions of the irregularities [the film thickness in the side wall surfaces/the film thickness in the bottom wall surfaces] not less than 0.01 and not more than 0.6, it is preferred that the proportion of oxygen in the processing gas be made in the range of 0.5% to 50%, and the processing pressure be made in the range of 6.7 to 133 Pa.

When it is intended to make the ratio of the thickness of a silicon oxide film in the side wall surfaces of surface irregularities to the thickness of a silicon oxide film in the bottom wall surfaces of the recessed portions of the irregularities [the film thickness in the side wall surfaces/the film thickness in the bottom wall surfaces] not less than 0.01 and not more than 0.4, it is preferred that the proportion of oxygen in the processing gas be made in the range of 0.5% to 25%, and the processing pressure be made in the range of 20 to 60 Pa.

In this embodiment, during the plasma oxidation processing, a high-frequency power, having a predetermined frequency and a predetermined power, is supplied from the high-frequency power source 44 to the stage 2 so as to apply a high-frequency bias to the substrate (wafer W). The frequency of the high-frequency power supplied from the high-frequency power source 44 is preferably in the range of 100 kHz to 60 MHz, more preferably in the range of 400 kHz to 13.5 MHz. The high-frequency power is preferably applied at a power density, per unit area of the wafer W, in the range of 0.2 to 2.3 W/cm², more preferably in the range of 0.35 to 1.2 W/cm². The high-frequency power is preferably in the range of 200 to 2000 W, more preferably in the range of 300 to 1200 W. The high-frequency power applied to the stage 2 has the effect of drawing ion species in the plasma to the wafer W while maintaining the low electron temperature of the plasma. The application of the high-frequency power therefore enhances anisotropy in plasma oxidation, making it possible to form a silicon oxide film having a significantly larger thickness in the bottom wall portions of the surface irregularities of the wafer than in the side wall portions. Because of the low-electron temperature plasma, the application of a high-frequency bias to the wafer W in this embodiment does not cause damage to a silicon oxide film by ions, etc. in the plasma. A good-quality silicon oxide film can thus be formed at a low temperature in a short time.

From the view point of decreasing radicals and enhancing anisotropy in oxidation, the power density of microwaves in plasma oxidation processing is preferably in the range of 0.255 to 2.55 W/cm². The power density of microwaves herein refers to the power of microwaves per unit area (cm²) of a wafer W. Thus, when processing a wafer W having a diameter of not less than 300 mm, for example, the power of microwaves is preferably made in the range of 500 to 5000 W, more preferably in the range of 1000 to 3000 W.

The wafer W heating temperature, i.e. the temperature of the stage 2, is preferably set in the range of room temperature (about 25° C.) to 600° C., more preferably in the range of 200° C. to 500° C., and desirably in the range of 400° C. to 500° C.

The above-described conditions are stored as a recipe in the storage unit 53 of the control section 50. The process controller 51 retrieves the recipe, and sends control signals to the components of the plasma processing apparatus 100, such as the gas supply mechanism 18, the exhaust device 24, the microwave generator 39, the heater power source 5a, the high-frequency power source 44, etc. to perform plasma oxidation processing under the intended conditions.

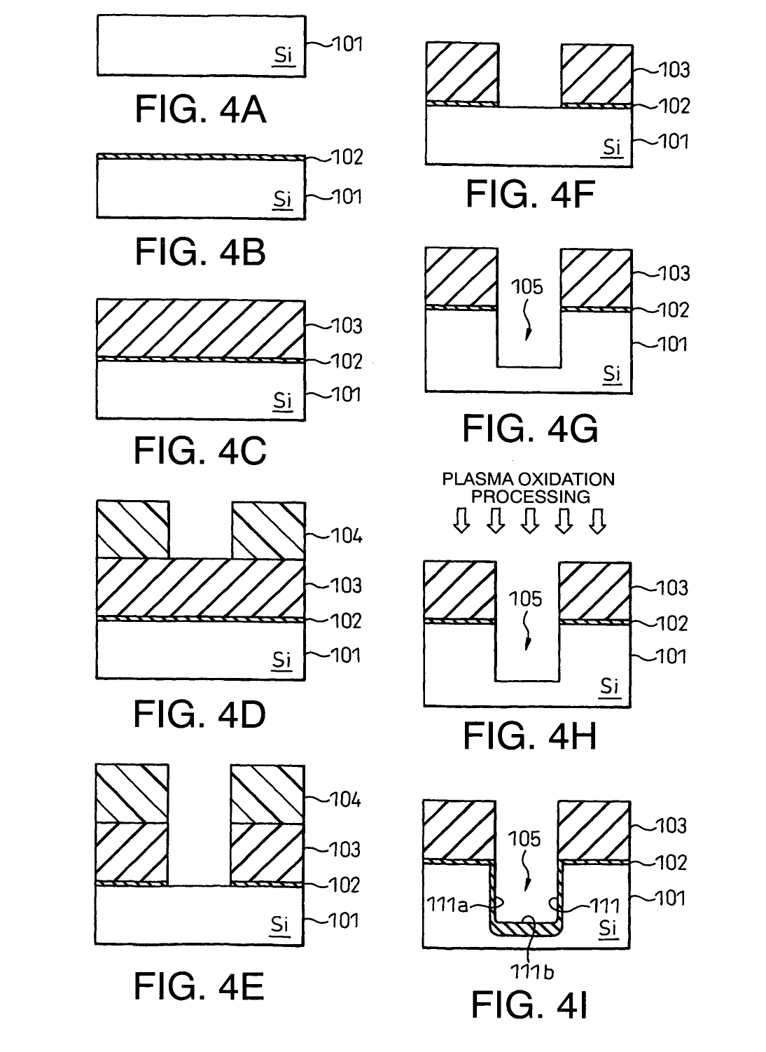

The formation of a silicon oxide film on the interior surfaces of trenches in STI, carried out by the silicon oxide film-forming method of the present invention, will now be described with reference to FIGS. 4A through 4I. FIGS. 4A though 4I illustrate process steps for the formation of trenches and the subsequent formation of an oxide film in STI.

Referring to FIGS. 4A and 4B, a silicon oxide film 102 such as SiO₂ is first formed on a silicon substrate 101 e.g. by thermal oxidation. Next, as shown in FIG. 4C, a silicon nitride film 103 such as Si₃N₄ is formed on the silicon oxide film 102 e.g. by CVD (chemical vapor deposition). Thereafter, as shown in FIG. 4D, after applying a photoresist onto the silicon nitride film 103, patterning is carried out by the photolithography technique to form a resist layer 104.

Next, selective plasma etching of the silicon nitride film 103 and the silicon oxide film 102 is carried out with the resist layer 104 as an etching mask, using e.g. a halogen etching gas, thereby exposing the silicon substrate 101 in accordance with the pattern of the resist layer 104 (FIG. 4E). Thus, a mask pattern for trenches is formed by the silicon nitride film 103. As shown in FIG. 4F, the resist layer 104 is then removed by so-called ashing as carried out by using an oxygen-containing plasma of a processing gas containing oxygen, etc.

Next, as shown in FIG. 4G, trenches 105 are formed by carrying out anisotropic plasma etching of the silicon substrate 101 with the silicon nitride film 103 and the silicon oxide film 102 as a mask. The etching can be carried out by using an etching gas containing a halogen or a halogen compound, such as Cl₂, HBr, SF₆ or CF₄, and optionally O₂.

FIG. 4H illustrates the step of forming a silicon oxide film in the trenches 105 of the wafer W after etching in STI. In this step, plasma oxidation processing is carried out under the conditions of: the proportion of oxygen in a processing gas in the range of 0.1% to 50%; and a processing pressure in the range of 1.3 to 667 Pa, while supplying a high-frequency power, having a frequency and a power (power density) in the above-described ranges, to the electrode 42 of the stage 2. By carrying out plasma oxidation processing under such conditions, the interior surfaces of the trenches 105 can be oxidized and a silicon oxide film 111 can be formed as shown in FIG. 4I. With reference to the silicon oxide film 111 thus formed by such selective oxidation, the ratio of the thickness of the silicon oxide film 111a formed on the side walls of the trenches 105 to the thickness of the silicon oxide film 111b formed on the bottoms of the trenches 105 [the thickness of silicon oxide film 111a/the thickness of silicon oxide film 111b] is not more than 0.6, for example, in the range of 0.01 to 0.6 (preferably in the range of 0.01 to 0.4). Thus, the thickness of the silicon oxide film 111a in the side wall portions of the trenches 105 can be made significantly small. Accordingly, when a gate electrode is formed, there is no decrease in the gate length. This enables the production of a finer device.

The larger the lateral thickness of the silicon oxide film 111a, formed in the silicon substrate 101 and on the side walls of the trenches 105 which are to be filled with a device isolation film in STI, the smaller is the area of a device formation region (e.g. a memory cell formation region in the case of a DRAM). For example, if the ratio of the thickness of the silicon oxide film 111a formed on the side walls of the trenches 105 to the thickness of the silicon oxide film 111b formed on the bottoms of the trenches 105 [the thickness of silicon oxide film 111a/the thickness of silicon oxide film 111b] exceeds 0.6, there will be an error in dimensional accuracy, making it difficult to respond to the demand for finer devices. Thus, in order to meet the demand for finer devices while sufficiently securing the area of device formation regions, it is necessary to selectively decrease as much as possible the thickness of the silicon oxide film 111a formed on the side walls of the trenches 105. According to this embodiment, in the oxidation processing of the interior surfaces of the trenches 105, the oxidation selectivity to the bottoms is enhanced to make the silicon oxide film 111a, formed on the side walls, significantly thinner than the silicon oxide film 111b formed on the bottoms. This makes it possible to respond to the demand for finer devices.

After forming the silicon oxide film 111 by the silicon oxide film-forming method of this embodiment, the subsequent steps are carried out in accordance with the usual procedure of STI for the formation of a device isolation region: An insulating film of e.g. SiO₂ is filled into the trenches 105 e.g. by CVD, followed by polishing by CMP (chemical mechanical polishing) with the silicon nitride film 103 as a stopper layer to flatten the surface. Thereafter, the silicon nitride film 103 and the upper portion of the embedded insulating film are removed by etching or CMP, thereby forming a device isolation structure.

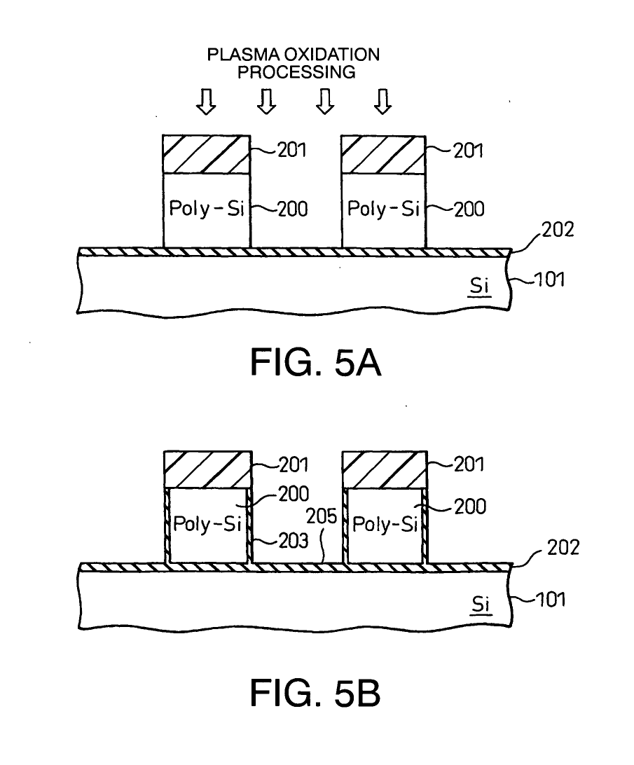

The silicon oxide film-forming method of this embodiment can also be applied to oxidation processing carried out to repair etching damage after etching for the formation of a gate electrode of a transistor. FIG. 5A illustrates plasma oxidation of polysilicon electrodes 200 which serve as gate electrodes of transistors. A polysilicon layer is formed on a silicon substrate 101 via an insulating film 202 of e.g. SiO₂. The polysilicon layer is plasma etched into a line and space pattern with the use of an etching mask 201 such as a resist, thereby forming the polysilicon electrodes 200. The plasma etching causes plasma damage to the side surfaces of the polysilicon electrodes 200 and to the substrate surface. In this embodiment, in order to repair the plasma damage, the silicon substrate 101 having the polysilicon electrodes 200 is subjected to plasma oxidation using the plasma processing apparatus 100 of FIG. 1. The plasma oxidation processing is carried out under the following conditions: the proportion of oxygen in a processing gas is not more than 50%, e.g. in the range of 0.1% to 50%; and the processing pressure is not more than 667 Pa, e.g. in the range of 1.3 to 667 Pa, while supplying a high-frequency power, having a frequency and a power (power density) in the above-described ranges, to the stage 2. As shown in FIG. 5B, a thin silicon oxide film 203 is formed by the plasma oxidation on the side surfaces of the polysilicon electrodes 200.

By performing a plasma oxidation process under the foregoing conditions, a silicon oxide film 203 is formed on the side wall of the polysilicon electrode 200, and a silicon oxide film 205 is formed on the surface of the silicon substrate 100. In this case, selective oxidation occurs so that the thickness of the silicon oxide film 203 formed on the side wall of the polysilicon electrode 200 is smaller than the thickness of the silicon oxide film 205 formed on the surface of the silicon substrate 100 which corresponds to the bottom of the irregularity. That is, [thickness of silicon oxide film 203/thickness of silicon oxide film 205], i.e., the ratio of the thickness of the silicon oxide film 203 formed on the side wall of the polysilicon electrode 200 to the thickness of the silicon oxide film 205 formed on the surface of the silicon substrate 100, is not more than 0.6, e.g., in the range of from not less than 0.01 to not more than 0.6, preferably, in the range of from not less than 0.01 to not more than 0.4. The growth of the silicon oxide film 203 on the side wall of the polysilicon electrode 200 is thus drastically suppressed.

A larger lateral thickness of the silicon oxide film 203, formed in the side wall portions of the polysilicon electrodes 200, leads to a smaller area (channel width) of the transistor formation region, producing a larger difference in the transistor design from the dimensions of the line and space pattern formed by etching. Thus, the difference or error can be too large for the intended design of fine transistors when the thickness of the silicon oxide film 203, formed on the side walls of the polysilicon electrodes 200, is large. Therefore, in order to ensure the area of transistor formation regions, it is necessary to minimize the thickness of the silicon oxide film 203 in the side wall portions of the polysilicon electrodes 200. In the silicon oxide film-forming method of this embodiment, the selectivity of oxidation to the silicon substrate 101 is enhanced so as to thin the silicon oxide film 203 formed on the side walls of the polysilicon electrodes 200. This makes it possible to maintain the dimensional accuracy and ensure the area of transistor formation regions, thus meeting the demand for finer devices.

On the other hand, the silicon oxide film 205 formed in the surface of the silicon substrate 100 should have a sufficient thickness for repairing of etching damage after etching for the formation of a gate electrode. With the silicon oxide film forming method in this embodiment, the oxidation selectivity between the silicon substrate 101 and the polysilicon electrode is high, so that the silicon oxide film 205 having a sufficient thickness can be formed on the silicon substrate 100, while suppressing the growth of the silicon oxide film 203 on the side wall of the polysilicon electrode 200. In FIG. 5, for the purpose of repairing of etching damage, the thickness of the silicon oxide film 205 may be not more than 20 nm, for example, in the range of from not less than 6 nm to not more than 20 nm, preferably, in the range of from not less than 6 nm to not more than 15 nm, and more preferably, in the range of from not less than 6 nm to not more than 8 nm.

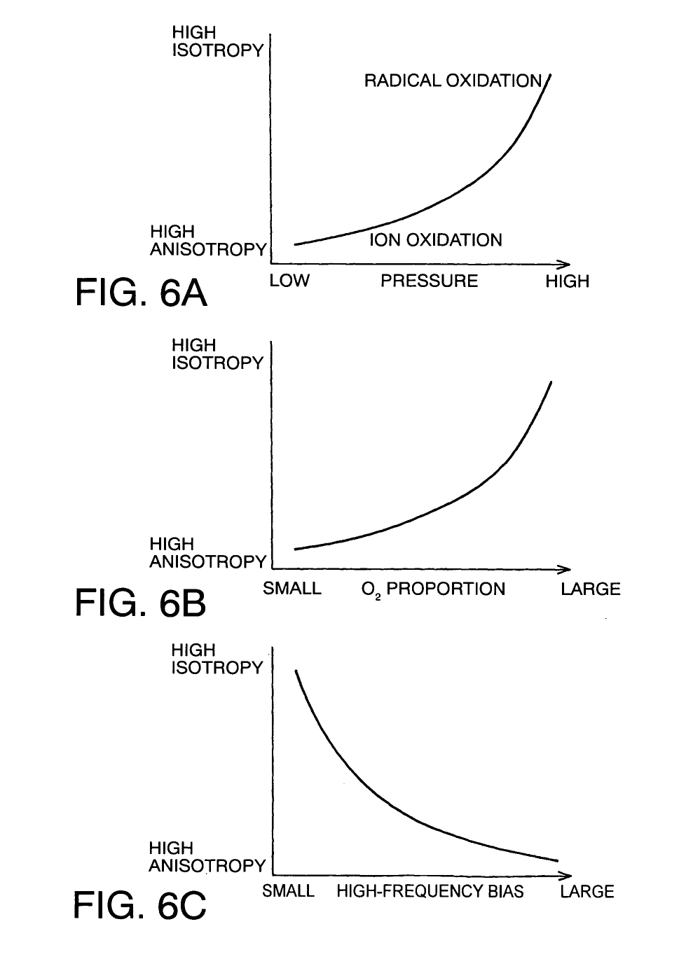

When carrying out plasma oxidation of a silicon surface having irregularities by using the plasma processing apparatus 100, the selectivity of oxidation between the bottoms and the side walls of the irregularities can be controlled mainly by adjusting the high-frequency power supplied to the stage 2, the processing pressure and the proportion of oxygen in the processing gas. For example, isotropy in oxidation increases with increase in the processing pressure because of increased radicals in plasma, as shown in FIG. 6A. To the contrary, anisotropy in oxidation increases with decrease in the processing pressure because of increased ions in plasma. As shown in FIG. 6B, isotropy in oxidation increases with increase in the proportion of O₂ gas in the processing gas because of decreased ions in plasma, whereas anisotropy in oxidation increases with decrease in the proportion of O₂ gas in the processing gas because of increased ions in plasma. Further, as shown in FIG. 6C, isotropy in oxidation is high when a low high-frequency power is supplied to the stage 2. Anisotropy in oxidation increases with increase in the high-frequency power because ions in plasma are more likely to be drawn to a wafer W.

According to the silicon oxide film-forming method of this embodiment, a high-frequency bias is applied to a substrate (wafer W) by supplying a high-frequency power to the stage 2. This causes ions in plasma to be drawn to the substrate (wafer W), thereby significantly increasing anisotropy in oxidation. In addition, the processing pressure is set not more than 667 Pa and the proportion of O₂ in the processing gas is set not more than 50%. With such processing conditions, oxidation mainly by ions as active oxidizing species is performed and the thickness of a silicon oxide film, formed on the bottoms of surface irregularities and on the side walls, is selectively controlled.

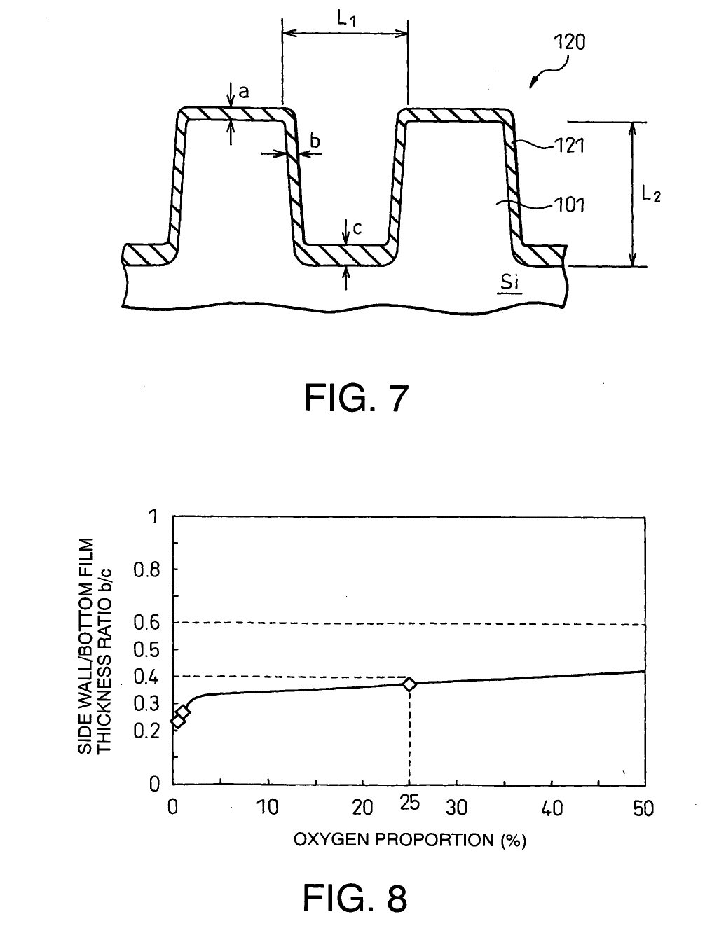

A description will now be given of an experiment which was conducted to confirm the technical effects of the present invention. The silicon oxide film-forming method of this embodiment was applied to the formation of an oxide film on a silicon surface in which a three-dimensional (line and space) pattern is formed. FIG. 7 schematically shows the cross-sectional structure of the surface of a wafer W after the formation of a silicon oxide film 121 by oxidation of the silicon surface of a silicon substrate 101 having a three-dimensional pattern 120. In this experiment, using the plasma processing apparatus 100 of FIG. 1, plasma oxidation processing of the silicon surface was carried out under the below-described varying conditions to form the silicon oxide film 121. After the processing of each wafer sample, a TEM photograph of the sample was shot. From the shot image were measured the film thickness “a” at the top of a raised portion in the three-dimensional pattern 120, the film thickness “b” in the side wall of a recessed portion, and the film thickness “c” in the bottom of the recessed portion. Further, the oxidation rates in the respective portions and the side wall/bottom film thickness ratio (b/c) were calculated. The opening width L₁ of the recessed portion was 130 nm, and the ratio of the depth L₂ of the recessed portion to the opening width L₁ (aspect ratio L₂/L₁) was 5.

The results are shown in Tables 1 through 3 and FIGS. 8 through 14. The side wall/bottom film thickness ratio (b/c) is an index of the selectivity of oxidation between the side wall and the bottom, and a smaller value indicates better selectivity. This is because the thickness “b” of the silicon oxide film in the side wall is preferably as small as possible from the viewpoint of responding to the demand for finer devices. The side wall/bottom film thickness ratio (b/c) is preferably not more than 0.6, more preferably not more than 0.4.

### <Common Conditions Between Examples 1 to 4>

Frequency of high-frequency bias: 13.56 MHz

Power of high-frequency bias: 600 W (power density 0.702 W/cm²)
Microwave power: 1200 W (power density 0.614 W/cm²)
Processing temperature: 465° C.
Target film thickness: 6 nm (top film thickness “a”)
Wafer diameter: 300 mm

### <Conditions in Comparative Example 1>

The same common conditions as in Examples 1 to 4 were used except that no high-frequency bias was applied.

TABLE 1

| | | | | | Comp. |
|---|---|---|---|---|---|
| | Example 1 | Example 2 | Example 3 | Example 4 | Ex. 1 |
| | 0.5% O₂ | 1% O₂ | 25% O₂ | 1% O₂ | 1% O₂ |
| Ar/O₂/H₂ volume ratio | 199/1/0 | 198/2/0 | 150/50/0 | 198/2/0 | 500/5/0 |
| [mL/min] | | | | | |
| Oxygen partial pressure | 0.2 | 0.4 | 10 | 1.33 | 1.32 |
| [pa] | | | | | |
| Processing pressure [pa] | 40 | 40 | 40 | 133 | 133 |
| Processing time [sec] | 180 | 135 | 120 | 320 | 315 |
| Side wall film thickness b | 2.31 | 2.10 | 2.92 | 3.15 | 5.6 |
| [nm] | | | | | |
| Bottom film thickness c | 9.82 | 7.62 | 7.76 | 8.62 | 4.4 |
| [nm] | | | | | |
| Sidewall oxidation rate | 0.77 | 0.93 | 1.46 | 0.59 | 1.06 |
| [nm/min] | | | | | |
| Bottom oxidation rate | 3.27 | 3.39 | 3.88 | 1.62 | 0.84 |
| [nm/min] | | | | | |
| Film thickness ratio b/c | 0.235 | 0.276 | 0.376 | 0.365 | 1.272 |
| b[nm] when c = 6 nm | 1.41 | 1.65 | 2.26 | 2.19 | — |
| Processing time* [sec] | 110 | 106 | 93 | 223 | 429 |

*Time it takes for the thickness of silicon oxide film reaches 6 nm in the bottom

As shown in Table 1, with reference to the side wall/bottom film thickness ratio b/c which is an index of the selectivity of oxidation between the side wall and the bottom, the film thickness ratio b/c is 1.272, indicating that the film is thicker in the side wall than in the bottom and that the oxidation progresses approximately isotropically, in Comp. Example 1 in which plasma oxidation processing is carried out without applying a high-frequency bias to the stage 2. In contrast, in Examples 1 to 4 in which plasma oxidation processing is carried out under the relatively low pressure conditions of 40 to 133 Pa while supplying a high-frequency power to the stage 2, the side wall/bottom film thickness ratio b/c is in the range of 0.235 to 0.376, thus indicating good results. These results demonstrate that in order to enhance the selectivity of oxidation to the bottom in plasma oxidation processing and thereby thin the film in the side wall, it is effective to select a relatively low pressure of not more than 133 Pa, e.g. a pressure in the range of 6.7 to 133 Pa, in addition to the application of a high-frequency bias to the stage 2. It also turns out that the use of a lower pressure can decrease the side wall/bottom film thickness ratio b/c and can thus decrease the film thickness in the side wall. This is supported by comparison of the data for the film thickness ratio b/c between Example 2 and Example 4 which both use the same 1% O₂ proportion.

Further, as can be seen from comparison between Examples 1 to 3 which all use the same processing pressure of 40 Pa, the use of a lower O₂ proportion can decrease the side wall/bottom film thickness ratio b/c. In particular, the side wall/bottom film thickness ratio b/c is 0.235 to 0.276 in Examples 1 and 2 in which the O₂ proportion is 0.5% to 1%. The results indicate that the film thickness in the side wall can be made smaller than that of Example 3 (side wall/bottom film thickness ratio b/c=0.376) in which the O₂ proportion is 25%. This is due to the fact that the decrease in the partial pressure of oxygen ions and radicals in the recessed portion leads to lowering of the oxidizing action on the side wall.

FIG. 8 is a graph showing the relationship between the proportion of oxygen in the processing gas and the side wall/bottom film thickness ratio b/c in the plasma oxidation processing in Examples 1 to 3. As can be seen from FIG. 8, at a processing pressure of 40 Pa, the side wall/bottom film thickness ratio b/c can be made not more than 0.6 by making the volume ratio of oxygen gas in the processing gas not more than 50%. The side wall/bottom film thickness ratio b/c can be made not more than 0.4 by making the volume ratio of oxygen gas not more than 25%.

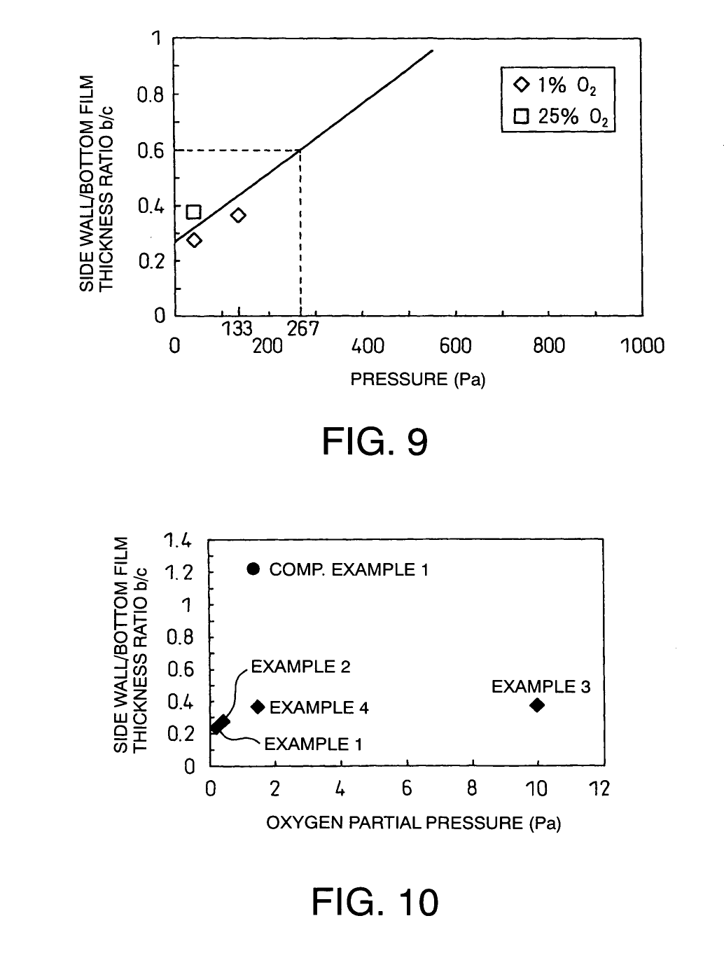

FIG. 9 is a graph showing the relationship between the processing pressure and the side wall/bottom film thickness ratio b/c in the plasma oxidation processing in Examples 2 to 4. As can be seen from FIG. 9, at an O₂ proportion of 0.1%, the side wall/bottom film thickness ratio b/c can be made not more than 0.6 by using a processing pressure of not more than 267 Pa. The side wall/bottom film thickness ratio b/c can be made not more than 0.4 and thus the film can be made thinner in the side wall by using a processing pressure of not more than 133 Pa.

FIG. 10 is a scatter plot graph showing the relationship between the partial pressure of oxygen in the processing gas and the side wall/bottom film thickness ratio b/c in the plasma oxidation processing in Examples 1 to 4 and Comp. Example 1. As can be seen from FIG. 10, in order to form a thin oxide film on the side wall with the side wall/bottom film thickness ratio b/c not more than 0.4, the partial pressure of oxygen in the processing gas is preferably made not more than 10, more preferably not more than 2.

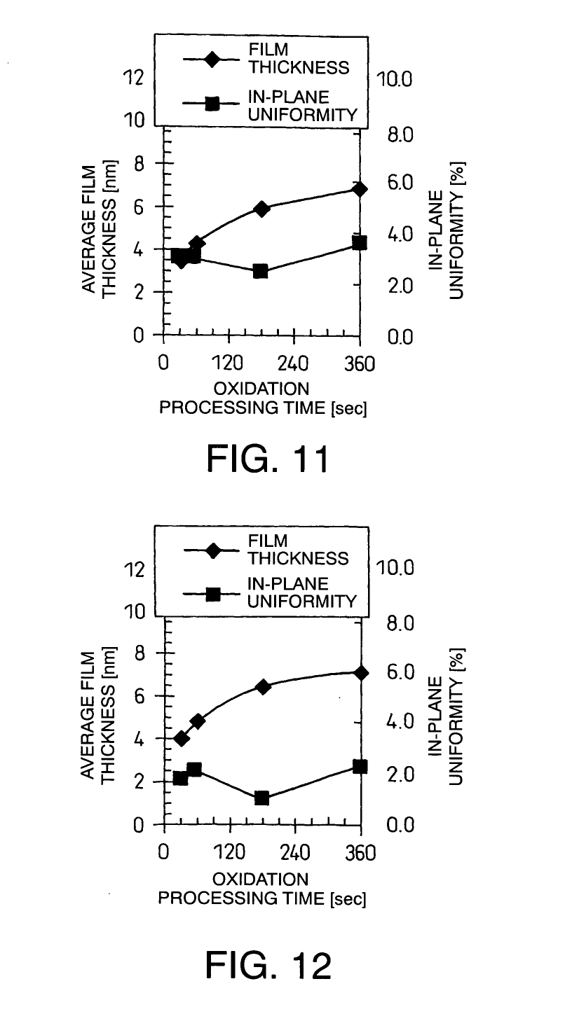

FIG. 11 is a graph showing the relationship between the plasma oxidation processing time and the average top film thickness “a” and the relationship between the plasma processing time and the in-plane uniformity of the average film thickness in wafer surface in Example 1. As shown in FIG. 11, in the plasma oxidation processing carried out under the conditions of Example 1, the target film thickness (top film thickness a=6 nm) is reached in about 180 seconds, indicating a sufficient oxidation rate. The in-plane uniformity in wafer surface satisfactorily changes in a range of up to 4%. The in-plane uniformity in wafer surface in FIG. 11 (also in FIGS. 12 and 14) is calculated as follows: (maximum film thickness in wafer surface−minimum film thickness)/(average film thickness in wafer surface×2)×100(%).

FIG. 12 is a graph showing the relationship between the plasma processing time and the average top film thickness “a” and the relationship between the plasma processing time and the in-plane uniformity of the average film thickness in wafer surface in Example 2. As shown in FIG. 12, in the plasma oxidation processing carried out under the conditions of Example 2, the target film thickness (top film thickness a=6 nm) is reached in about 135 seconds, indicating a sufficient oxidation rate. The in-plane uniformity in wafer surface very satisfactorily changes in a range of up to 2%.

The data in FIGS. 11 and 12 thus demonstrates that practically sufficient oxidation rate and in-plane uniformity in wafer surface can be obtained also with the plasma oxidation conditions of Example 1 or 2 which provide the side wall/bottom film thickness ratio b/c of not more than 0.4.

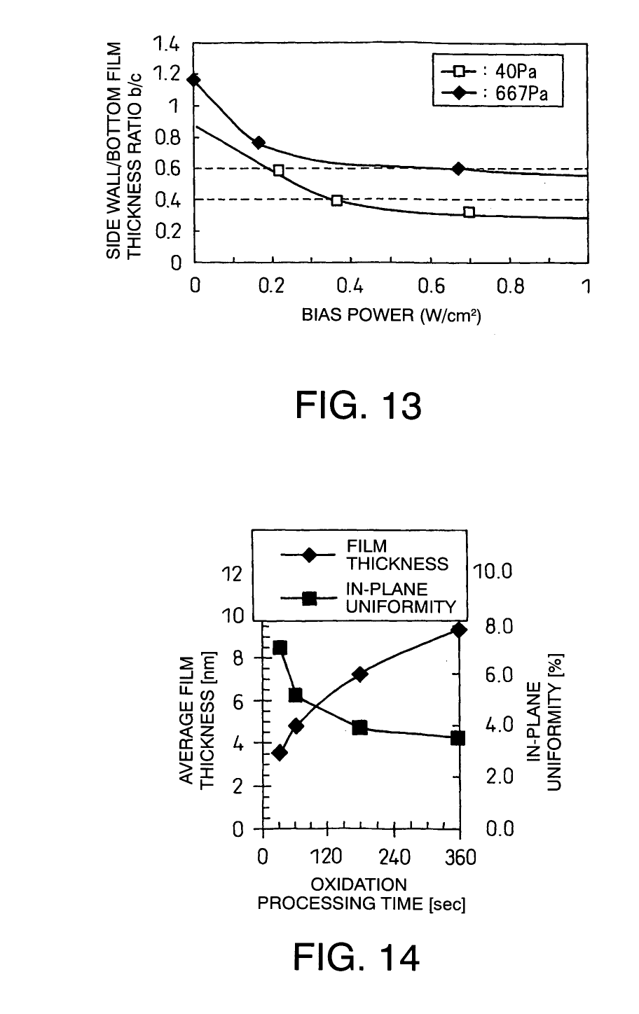

Examples 5 to 8 and Comparative Examples 2 and 3, which all use a processing gas containing hydrogen, will now be described with reference to Tables 2 and 3 and FIGS. 13 and 14.

### <Common Conditions Between Examples 5 to 8 and Comparative Example 3>

Frequency of high-frequency bias: 13.56 MHz
Microwave power: 1200 W (power density 0.614 W/cm²)
Processing temperature: 465° C.
Target film thickness: 6 nm (top film thickness “a”)
Wafer diameter: 300 mm

### <Conditions in Comparative Example 2>

The same common conditions as in Examples 5 to 8 and Comp. Example 3 were used except that no high-frequency bias was applied.

TABLE 2

| | Example 5 | Example 6 | Example 7 | Example 8 |
|---|---|---|---|---|
| | (23% O₂/ | (0.5% O₂/ | (0.5% O₂/ | (0.5% O₂/ |
| | 2% H₂) | 0.5% H₂) | 0.5% H₂) | 0.5% H₂) |
| Ar/O₂/H₂ volume ratio | 1200/370/32 | 198/1/1 | 198/1/1 | 198/1/1 |
| [mL/min] | | | | |
| Oxygen partial | 154 | 0.2 | 0.2 | 0.2 |
| pressure [pa] | | | | |
| Hydrogen partial | 12.5 | 0.2 | 0.2 | 0.2 |
| pressure[pa] | | | | |
| Bias power density | 0.67 | 0.2 | 0.35 | 0.7 |
| [W/cm²] | | | | |
| Processing pressure | 667 | 40 | 40 | 40 |
| [pa] | | | | |
| Processing time | 45 | 55 | 80 | 90 |
| [sec] | | | | |
| Side wall film | 4.1 | 4.7 | 4.2 | 3.56 |
| thickness b [nm] | | | | |
| Bottom film | 6.7 | 7.6 | 10.5 | 10.65 |
| thickness c [nm] | | | | |
| Sidewall oxidation rate | 2.05 | 5.12 | 3.15 | 2.37 |
| [nm/min] | | | | |
| Bottom oxidation rate | 8.93 | 8.5 | 7.9 | 7.10 |
| [nm/min] | | | | |
| Film thickness ratio | 0.6 | 0.6 | 0.4 | 0.3 |
| b/c | | | | |
| H₂/(H₂ + O₂) flow rate | 7.5 | 50 | 50 | 50 |
| ratio [%] | | | | |
| Processing time* [sec] | 40 | 42 | 46 | 51 |

*Time it takes for the thickness of silicon oxide film reaches 6 nm in the bottom

TABLE 3

| | Comp. | Comp. |
|---|---|---|
| | Example 2 | Example 3 |
| | (23% O₂/2% H₂) | (23% O₂/2% H₂) |
| Ar/O₂/H₂ volume ratio | 1200/370/30 | 1200/370/31 |
| [mL/min] | | |
| Oxygen partial pressure | 154 | 154 |
| [pa] | | |
| Hydrogen partial | 12.5 | 12.5 |
| pressure[pa] | | |
| Bias power density | 0 | 0.16 |
| [W/cm²] | | |
| Processing pressure [pa] | 667 | 667 |
| Processing time [sec] | 710 | 105 |
| Side wall film thickness b | 7.2 | 4.7 |
| [nm] | | |
| Bottom film thickness c | 6.5 | 6.1 |
| [nm] | | |
| Sidewall oxidation rate | 0.61 | 2.68 |
| [nm/min] | | |
| Bottom oxidation rate | 0.55 | 3.48 |
| [nm/min] | | |
| Film thickness ratio b/c | 1.2 | 0.8 |
| H₂/(H₂ + O₂) flow rate ratio | 7.5 | 7.5 |
| [%] | | |
| Processing time* [sec] | 652 | 103 |

*Time it takes for the thickness of silicon oxide film reaches 6 nm in the bottom

The data in Tables 2 and 3 demonstrates that the oxidation rate can be considerably increased by carrying out plasma oxidation processing with the use of a processing gas containing H₂ and with the application of a high-frequency bias power to the stage 2. The proportion of hydrogen is preferably not less than 0.1% and less than 2%, more preferably 0.1% to 1%. The selectivity of oxidation between the side wall and the bottom (i.e. the side wall/bottom film thickness ratio b/c) is practically sufficient (the side wall/bottom film thickness ratio b/c=0.3-0.6) also in the plasma oxidation processing using the H₂-containing processing gas when the processing is carried out while applying a high-frequency bias power to the stage 2 at a power density of not less than 0.2 [W/cm²] as in Examples 5 to 8. Especially in Example 8 in which plasma oxidation processing is carried out at a processing pressure of 40 Pa, the film thickness ratio b/c is 0.3. Thus, both high oxidation rate and high selectivity of oxidation to the bottom, i.e. significantly decreased film thickness in the side wall, can be achieved. The experimental results thus demonstrate that the use of H₂ in a processing gas can increase the oxidation rate, thereby increasing the throughput.

FIG. 13 shows the relationship between the power density (bias power) of a high-frequency bias and the side wall/bottom film thickness ratio b/c in Examples 5 to 8 and Comp. Examples 2 and 3. As can be seen from Table 2 and FIG. 13, when the processing pressure is 667 Pa, the side wall/bottom film thickness ratio b/c can be made not more than 0.6 and thus the film can be made thin in the side wall by applying a high-frequency bias to the processing object at a power density of not less than 0.2 [W/cm²]. When the processing pressure is 40 Pa, the side wall/bottom film thickness ratio b/c can be made not more than 0.6 by applying a high-frequency bias to the processing object at a power density of not less than 0.2 [W/cm²]; and the side wall/bottom film thickness ratio b/c can be made not more than 0.4 and thus the film can be made thinner in the side wall by applying a high-frequency bias to the processing object at a power density of not less than 0.35 [W/cm²].

On the other hand, despite the use of the hydrogen-containing processing gas, a sufficient oxidation rate cannot be obtained and the side wall/bottom film thickness ratio b/c is 0.8 to 1.2, indicating low oxidation selectivity to the bottom, in Comp. Example 2 in which no high-frequency bias is applied to the processing object (wafer W) and in Comp. Example 3 in which the power density of the high-frequency bias is as small as 0.16 [W/cm²]. Thus, it turns out that when it is intended to increase the oxidation rate in plasma oxidation while obtaining high oxidation selectivity to the bottom, i.e. small film thickness in the side wall, it is preferred to use an H₂-containing processing gas and apply a high-frequency bias power to the state 2.

FIG. 14 is a graph showing the relationship between the plasma oxidation processing time and the average top film thickness “a” and the relationship between the plasma oxidation processing time and the in-plane uniformity of the average film thickness in wafer surface in Example 8. As shown in FIG. 14, in the plasma oxidation processing carried out under the conditions of Example 8, the target film thickness (top film thickness a=6 nm) is reached in about 90 seconds, indicating a very high oxidation rate. The experimental results thus demonstrate that the use of H₂ in the processing gas can achieve the high oxidation rate of 7.1 nm/min and, therefore, achieve a high throughput while providing a thin oxide film on the side wall.

As described in detail hereinabove, in carrying out oxidation processing of a silicon portion, exposed on the surface of a wafer W having a three-dimensional pattern, with a plasma of a processing gas to form a silicon oxide film, using the plasma processing apparatus 100, the side wall/bottom film thickness ratio b/c can be made not more than 0.6, e.g. in the range of 0.01 to 0.6, by making the proportion of oxygen in the processing gas within the range of 0.1% to 50% and using a processing pressure in the range of 1.3 to 667 Pa. Therefore, by using the above method, a silicon oxide film can be selectively formed, having a sufficient thickness in the bottom portions of a three-dimensional surface pattern, while making the film as thin as possible in the side wall portions of the pattern, e.g. in oxidation of the interior surfaces of trenches in STI or in oxidation to repair etching damage after etching for the formation of a gate electrode of a transistor. Consequently, the accuracy of lateral dimensions of the three-dimensional pattern can be ensured, enabling the design of fine devices.

Further, the use of H₂ in a processing gas can achieve a high oxidation rate and form a thin silicon oxide film in a short time, with a film thickness of not more than 20 nm, e.g. in the range of 6 to 20 nm, in the bottom wall surfaces of surface irregularities and a film thickness of not less than 0.6 nm and not more than 12 nm in the side walls of the irregularities.

In the method for forming a silicon oxide film in the foregoing embodiments, plasma oxidation of a processing object having surface irregularities, placed on the stage, is carried out while applying a high-frequency power to the stage at a power output in the range of 0.2 to 2.3 W/cm² per unit area of the processing object, keeping the proportion of oxygen in the processing gas in the range of 0.1 to 50% by volume, and keeping the processing pressure in the range of 1.3 to 667 Pa, whereby the ratio of the thickness of the resulting oxide film in the side wall surfaces of the irregularities to that in the bottom wall surfaces [the film thickness in the side wall surfaces/the film thickness in the bottom wall surfaces] is made not more than 0.6. By carrying out such highly anisotropic oxidation processing with high selectivity, a silicon oxide film can be formed, having a sufficient thickness in the bottom wall surfaces of the recessed portions of surface irregularities, while making the film as thin as possible in the side wall surfaces of the irregularities, e.g. in the formation of a silicon oxide film in trenches in STI or in the formation of a silicon oxide film to repair damage after etching for forming a gate electrode. Therefore, by using the silicon oxide film-forming method of the present invention in the manufacturing of various devices, it becomes possible to ensure dimensional accuracy for device regions with minimum loss of lateral dimensions, thus meeting the demand for finer devices.

While the present invention has been described with reference to preferred embodiments, it is understood that the present invention is not limited to the embodiments, but is capable of various modifications. For example, though in the embodiments the RLSA-type plasma processing apparatus is used as an optimal apparatus for carrying out the silicon oxide film-forming method of the present invention, it is also possible to use other types of plasma processing apparatuses, such as ICP plasma type, ECR plasma type, surface reflected wave plasma type, magnetron plasma type, etc.

The formation of a silicon oxide film on a three-dimensional pattern has been described in the exemplary cases of: oxidation in the trenches 105 of the monocrystalline silicon substrate 101 in STI; and oxidation to repair etching damage after the formation of a polysilicon gate electrode of a transistor by etching. However, the silicon oxide film-forming method of the present invention finds other various applications for which the formation of a silicon oxide film on the surface of a three-dimensional pattern is needed. The present invention is also applicable to the formation of a silicon oxide film, e.g. as an insulating film, which is to be formed selectively thin in the side walls of surface irregularities, on a silicon surface in which there is a plane orientation difference due to the irregularities, for example in the process of manufacturing a three-dimensional transistor e.g. having a fin structure or a trench gate structure. The present invention is also applicable to the formation of a silicon oxide film which is to be formed selectively thick in the bottoms of irregularities of a silicon surface.

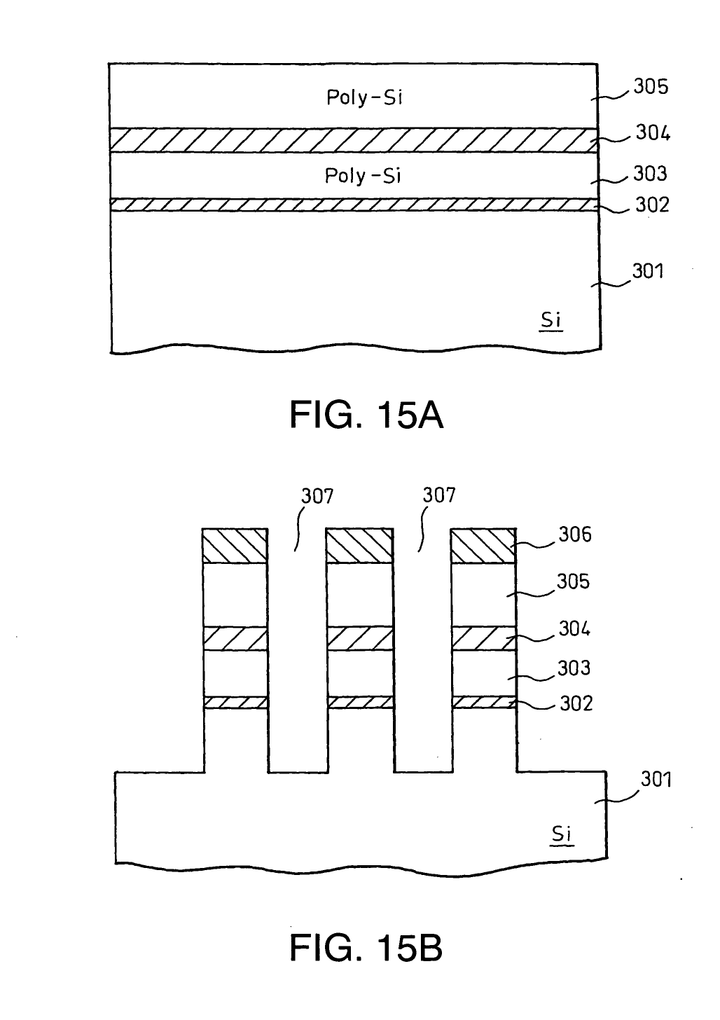

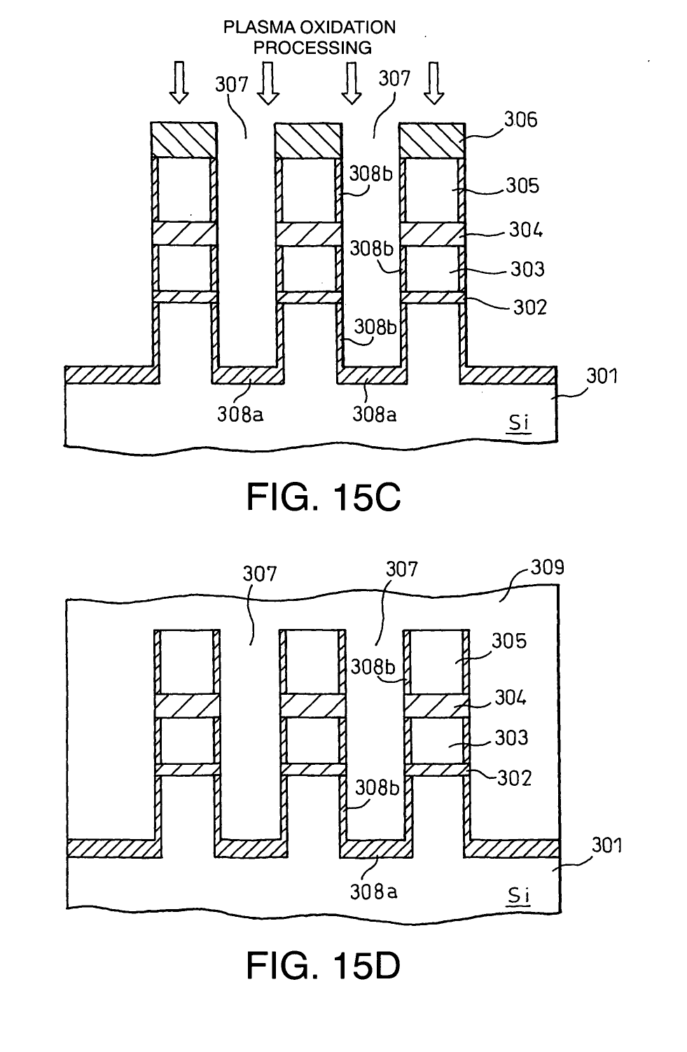

FIGS. 15A through 15D illustrate a silicon oxide-film forming method according to the present invention as applied in a flash memory manufacturing process. As shown in FIG. 15A, a silicon substrate 301 is first subjected to thermal oxidation to form a first insulating film layer 302 of SiO₂ on the silicon substrate 301. Next, a first polysilicon layer 303, a second insulating film layer 304 consisting of an Si₃N₄ layer and an SiO₂ layer, and a second polysilicon layer 305 are sequentially formed by CVD. As is well known, in a flash memory device the first insulating layer 302 acts as a tunnel oxide film, the first polysilicon layer 303 acts as a floating gate, and the second polysilicon layer 305 acts as a control gate. The above method for forming these layers on the silicon substrate 301 is also well known.

Though not shown in FIG. 15A, a photoresist is then applied onto the second polysilicon layer 305, followed by patterning of the photoresist by the photolithography technique to form a mask 306 for etching. Thereafter, using the mask 306, plasma etching, for example, is carried out to simultaneously form trenches 307 in the silicon substrate 301, thereby isolating memory regions, as shown in FIG. 15B.

Next, as shown in FIG. 15C, plasma oxidation processing of the trenches 307 is carried out according to the method of the present invention to form a silicon oxide film 308 on the interior surfaces of the trenches 307. The silicon oxide film 308 can be formed such that the thickness of the silicon oxide film 308a in the side walls of the trenches 307 is significantly smaller than the thickness of the silicon oxide film 308b in the bottoms. Therefore, a long gate length can be secured for each memory device.

Next, as shown in FIG. 15D, the mask 306 is removed e.g. by ashing, and metal interconnects (not shown) are formed as necessary. Thereafter, an interlevel insulating film 309 of e.g. SiO₂ is formed e.g. by CVD or plasma CVD to bury the memory regions in the insulating film 309, thereby completing the production of the flash memory. As described above, in the flash memory, the silicon oxide film formed on the side walls of each memory device can be made very thin. Accordingly, a long gate length can be secured even for a fine device. It thus becomes possible to obtain a flash memory having a large memory capacity and high operational reliability.

1. A method for forming a silicon oxide film by allowing a plasma of a processing gas to act on a silicon portion, exposed on a surface of a processing object having irregularities in the surface, to oxidize the silicon portion in a processing chamber of a plasma processing apparatus, said method comprising generating the plasma under the following conditions: the proportion of oxygen in the processing gas is in the range of 0.1 to 50% by volume; and the processing pressure is in the range of 1.3 to 667 Pa, while applying a high-frequency power to a stage, disposed in the processing chamber and on which the processing object is placed, at a power output in the range of 0.2 to 2.3 W/cm² per unit area of the processing object, whereby silicon oxide films are formed on side wall surfaces of the irregularities and bottom wall surfaces of recessed portions of the irregularities in such a manner that the ratio of the thickness of the silicon oxide film formed on the side wall surfaces of the irregularities to the thickness of the silicon oxide film formed on the bottom wall surfaces of the recessed portions of the irregularities is made not more than 0.6, and that the thickness of the silicon oxide films formed on the bottom wall surfaces is not less than 6 nm and not more than 20 nm.

2. The method for forming a silicon oxide film according to claim 1, wherein the proportion of oxygen in the processing gas is made not less than 0.5% by volume and not more than 50% by volume and the processing pressure is made not less than 6.7 Pa and not more than 133 Pa, whereby the ratio of the thickness of the silicon oxide film formed on the side wall surfaces of the irregularities to the thickness of the silicon oxide film formed on the bottom wall surfaces of the recessed portions of the irregularities is made not less than 0.01 and not more than 0.6.

3. The method for forming a silicon oxide film according to claim 1, wherein the proportion of oxygen in the processing gas is made not less than 0.5% by volume and not more than 25% by volume and the processing pressure is made not less than 20 Pa and not more than 60 Pa, whereby the ratio of the thickness of the silicon oxide film formed on the side wall surfaces of the irregularities to the thickness of the silicon oxide film formed on the bottom wall surfaces of the recessed portions of the irregularities is made not less than 0.01 and not more than 0.4.

4. The method for forming a silicon oxide film according to claim 1, wherein the processing gas contains hydrogen.

5. The method for forming a silicon oxide film according to claim 4, wherein the ratio of the flow rate of hydrogen to the total flow rate of hydrogen and oxygen in the processing gas is in the range of 1% to 90%.

6. The method for forming a silicon oxide film according to claim 1, wherein the frequency of the high-frequency power is in the range of 100 kHz to 60 MHz.

7. The method for forming a silicon oxide film according to claim 1, wherein the processing temperature is in the range of room temperature to 600° C.

8. The method for forming a silicon oxide film according to claim 1, wherein the plasma is a microwave-excited plasma formed by the processing gas and microwaves introduced into the processing chamber by means of a plane antenna having a plurality of slots.

9. The method for forming a silicon oxide film according to claim 8, wherein the power density of the microwaves per unit area of the processing object is in the range of 0.255 to 2.55 W/cm².

10. A computer-readable storage medium in which is stored a control program which operates on a computer, said control program, upon its execution, causing the computer to control a plasma processing apparatus such that it carries out a method for forming a silicon oxide film by allowing a plasma of a processing gas to act on a silicon portion, exposed on a surface of a processing object having irregularities in the surface, to oxidize the silicon portion in a processing chamber of the plasma processing apparatus, wherein said plasma is generated under the following conditions: the proportion of oxygen in the processing gas is in the range of 0.1 to 50% by volume; and the processing pressure is in the range of 1.3 to 667 Pa, while applying a high-frequency power to a stage, disposed in the processing chamber and on which the processing object is placed, at a power output in the range of 0.2 to 2.3 W/cm² per unit area of the processing object, whereby silicon oxide films are formed on side wall surfaces of the irregularities and bottom wall surfaces of recessed portions of the irregularities in such a manner that the ratio of the thickness of the silicon oxide film formed on the side wall surfaces of the irregularities to the thickness of the silicon oxide film formed on the bottom wall surfaces of the recessed portions of the irregularities is made not more than 0.6, and that the thickness of the silicon oxide films formed on the bottom wall surfaces is not less than 6 nm and not more than 20 nm.

11. A plasma processing apparatus comprising:
an open-topped processing chamber for processing a processing object by using a plasma;
a dielectric member which closes the opening of the processing chamber;
an antenna, provided outside the dielectric member, for introducing electromagnetic waves into the processing chamber;
a gas supply mechanism for supplying a raw material gas into the processing chamber;
an exhaust mechanism for depressurizing and evacuating the processing chamber;
a stage, disposed in the processing chamber, for placing the processing object thereon;
a high-frequency power source connected to the stage; and
a control section which, when forming a silicon oxide film by oxidizing a silicon portion, exposed on a surface of the processing object having irregularities in the surface, with a plasma of a processing gas in the processing chamber, controls the apparatus such that it generates the plasma by introducing electromagnetic waves into the processing chamber by means of the antenna while applying a high-frequency power to the stage at a power output in the range of 0.2 to 2.3 W/cm² per unit area of the processing object, keeping the proportion of oxygen in the processing gas, supplied by the gas supply mechanism, in the range of 0.1 to 50% by volume, and keeping the processing pressure in the range of 1.3 to 667 Pa by means of the exhaust mechanism, whereby silicon oxide films are formed on side wall surfaces of the irregularities and bottom wall surfaces of recessed portions of the irregularities in such a manner that the ratio of the thickness of the silicon oxide film formed on the side wall surfaces of the irregularities to the thickness of the silicon oxide film formed on the bottom wall surfaces of the recessed portions of the irregularities is made not more than 0.6, and that the thickness of the silicon oxide films formed on the bottom wall surfaces is not less than 6 nm and not more than 20 nm.

12. The method for forming a silicon oxide film according to claim 1, wherein the thickness of the silicon oxide film formed on the side wall surfaces is not less than 2 nm and not more than 5 nm.
